(19) United States
(12) Patent Application Publication
(10) Pub. No.: US 2024/0206182 A1
(43) Pub. Date: Jun. 20, 2024

(54) NON-VOLATILE MEMORY DEVICE

(71) Applicant: Samsung Electronics Co., Ltd., Suwon-si (KR)

(72) Inventors: Changmin CHOI, Suwon-si (KR); Ryoongbin LEE, Suwon-si (KR); Dongjin LEE, Suwon-si (KR); Junhee LIM, Suwon-si (KR)

(21) Appl. No.: 18/523,033

(22) Filed: Nov. 29, 2023

(30) Foreign Application Priority Data
Dec. 19, 2022 (KR) 10-2022-0178682

(51) Int. Cl. H10B 43/40; H10B 41/10; H10B 41/40; H10B 43/10

(52) U.S. Cl. CPC H10B 43/40; H10B 41/10; H10B 41/40; H10B 43/10

(57) ABSTRACT

A non-volatile memory device including a memory cell array including a plurality of word lines stacked on a substrate in a first direction perpendicular to an upper surface of the substrate, and a common source line below the plurality of word lines, a plurality, of driving signal lines connected to a row decoder, and a plurality of pass transistor arrays each including a plurality of vertical pass transistors respectively connected the plurality of driving signal lines and the plurality of word lines, wherein each of the plurality of pass transistor arrays further include an active region including a drain to which at least two of the plurality of vertical pass transistors are simultaneously bonded, and a main contact applying a signal to the active region.

### CROSS-REFERENCE TO RELATED APPLICATION

Korean Patent Application No. 10-2022-0178682, filed on Dec. 19, 2022, in the Korean Intellectual Property Office, is incorporated by reference herein in its entirety.

### BACKGROUND

### 1. Field

A non-volatile memory device is disclosed.

### 2. Description of the Related Art

Recently, as information communication devices become multifunctional, memory devices are required to have large capacity and high integration.

### SUMMARY

Embodiments are directed to a non-volatile memory device including a memory cell array including a plurality of word lines stacked on a substrate in a first direction perpendicular to an upper surface of the substrate, and a common source line below the plurality of word lines, a plurality of driving signal lines connected to a row decoder, and a plurality of pass transistor arrays each including a plurality of vertical pass transistors respectively connected the plurality of driving signal lines and the plurality of word lines, wherein each of the plurality of pass transistor arrays further include an active region including a drain to which at least two of the plurality of vertical pass transistors are simultaneously bonded, and a main contact applying a signal to the active region.

Embodiments are directed to a non-volatile memory device including a memory cell array including a first word line, a second word line stacked on the first word line, a third word line stacked on the second word line, and a fourth word line stacked on the third word line, and first to fourth vertical pass transistors respectively connected to the first word line to the fourth word line, wherein two or more of the first to fourth vertical pass transistors share one drain of an active region.

Embodiments are directed to an electronic system including a main substrate, a non-volatile memory device on the main substrate, and a controller electrically connected to the non-volatile memory device on the main substrate, wherein the non-volatile memory device includes a first semiconductor layer including a memory cell array including a plurality of word lines stacked in a vertical direction and a common source line below the plurality of word lines, a row decoder, and a plurality of vertical pass transistors connected between the plurality of word lines and the row decoder, and a second semiconductor layer including a page buffer connected to the memory cell array, and below the first semiconductor layer in the vertical direction, the plurality of vertical pass transistors sharing a drain of an active region and sharing a main contact, the main contact applying a signal to the active region.

### BRIEF DESCRIPTION OF THE DRAWINGS

Features will become apparent to those of skill in the art by describing in detail exemplary embodiments with reference to the attached drawings in which:

FIG. 1 is a block diagram showing a memory device according to an example embodiment.

FIG. 2 is a diagram showing a structure of a memory device according to an example embodiment.

FIG. 3 is a diagram showing, a memory cell array according to an example embodiment.

FIG. 4 is a diagram showing an equivalent circuit of a memory block according to an example embodiment.

FIG. 5 is a diagram showing a driving signal line decoder, a pass transistor circuit, and a memory block, according to an example embodiment.

FIG. 6 is a diagram showing a pass transistor array according to an example embodiment.

FIG. 7A is a cross-sectional view showing the pass transistor array taken along line AA′ of FIG. 6.

FIG. 7B is a cross-sectional view showing the pass transistor array taken along line BB′ of FIG. 6.

FIGS. 8A to 8I show steps in a method of forming a pass transistor array according to an example embodiment.

FIG. 9 is a diagram showing pass transistor arrays according to an example embodiment.

FIG. 10 is a diagram showing pass transistor arrays according to an example embodiment,

FIG. 11 is a diagram showing pass transistor arrays according to an example embodiment.

FIG. 12 is a diagram showing pass transistor arrays according to an example embodiment.

FIG. 13 is a diagram showing a data storage system including a memory device according to an example embodiment.

FIG. 14 is a perspective view showing a data storage system including a memory device according to an example embodiment.

FIG. 15 is a cross-sectional view showing the semiconductor package taken along line II-II′ of FIG. 14.

### DETAILED DESCRIPTION

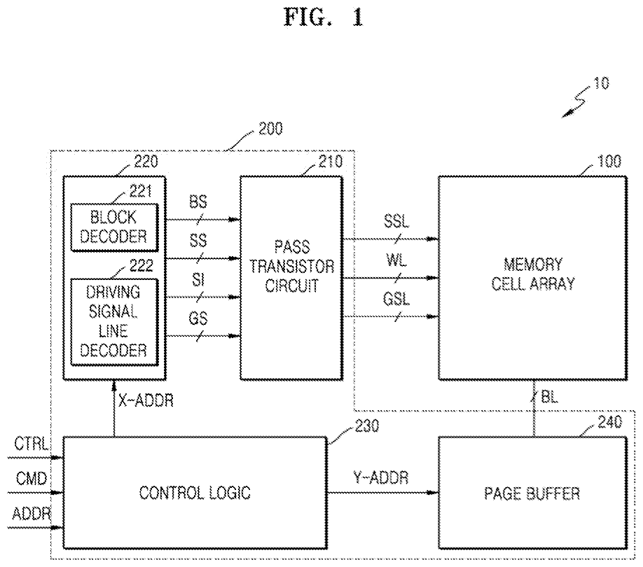

FIG. 1 is a block diagram showing a memory device 10 according to an example embodiment. Referring to FIG. 1, the memory device 10 may include a memory cell array 100 and a peripheral circuit 200. The peripheral circuit 200 may include a pass transistor circuit 210, a row decoder 220, a control logic 230, and a page buffer 240. The peripheral circuit 200 may further include a voltage generation unit, a data input/output circuit, an input/output interface, a column logic, a pre-decoder, a temperature sensor, a command decoder, or an address decoder. In embodiments, the memory device 10 may be a non-volatile memory device, and hereinafter, the “memory device” is referred to as a non-volatile memory device. As used herein, the term “or” is not an exclusive term, e.g., “A or B” would include A. B, or A and B.

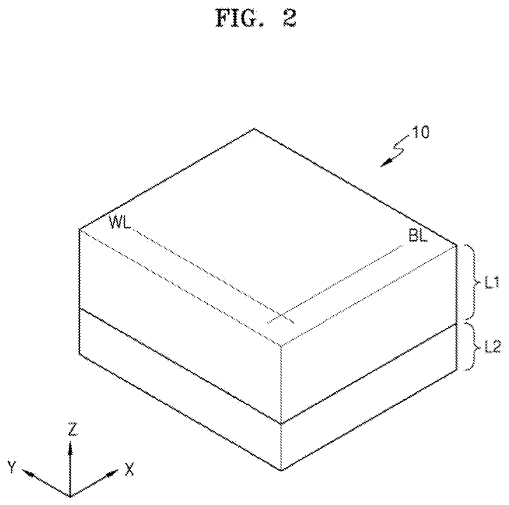

In an embodiment, the memory cell array 100, the pass transistor circuit 210, and the row decoder 220 may be in a first semiconductor layer (e.g., L1 of FIG. 2). The control logic 230 and the page buffer 240 may be in a second semiconductor layer (e.g., L2 of FIG. 2) below the first semiconductor layer. In another embodiment, the memory cell array 100 and the pass transistor circuit 210 may be in the first semiconductor layer, and the row decoder 220, the control logic 230, and the page buffer 240 may be in the second semiconductor layer. In another embodiment, some of circuits constituting the row decoder 220 may be in the first semiconductor layer together with the memory cell array 100 and the pass transistor circuit 210, and some other of the circuits constituting the row decoder 220, the control logic 230, and the page buffer 240 may be in the second semiconductor layer.

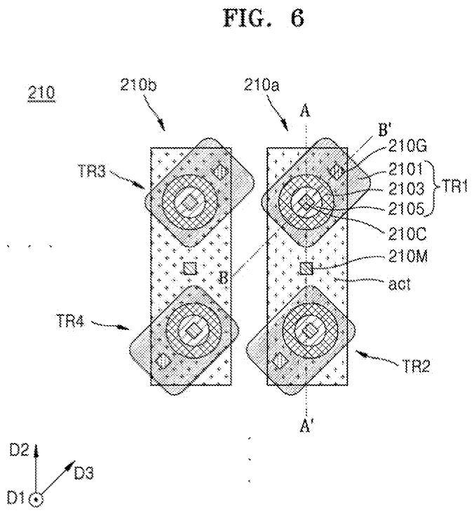

In an embodiment, the pass transistor circuit 210 may include a plurality of pass transistor arrays (e.g., first and second pass transistor arrays 210a and 210b of FIG. 6). In an implementation, the plurality of pass transistor arrays may be in the first semiconductor layer.

The memory cell array 100 may be connected to the page buffer 240 through bit lines BL. The memory cell array 100 may be connected to the pass transistor circuit 210 through word lines WL, string selection lines SSL, and ground selection lines GSL. Also, the pass transistor circuit 210 may be connected to the row decoder 220 through block selection signal lines BS, string selection line driving signal lines SS, word line driving signal lines SI, and ground selection line driving signal lines GS. The string selection line driving signal lines SS, the word line driving signal lines SL and the ground selection line driving signal lines GS may be referred to as “driving signal lines”.

Also, the memory cell array 100 may include a plurality of memory cells, and the memory cells may be, e.g., flash memory cells. Hereinafter, embodiments are described in detail taking a case where the plurality of memory cells are NAND flash memory cells as an example, in some embodiments, the plurality of memory cells may be resistive memory cells, such as random access memory (RAM) (ReRAM), phase change RAM (PRAM), or magnetic RAM (MRAM).

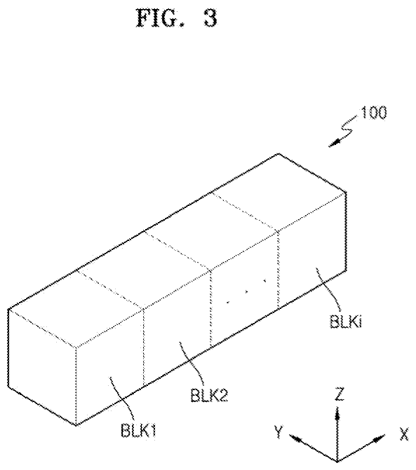

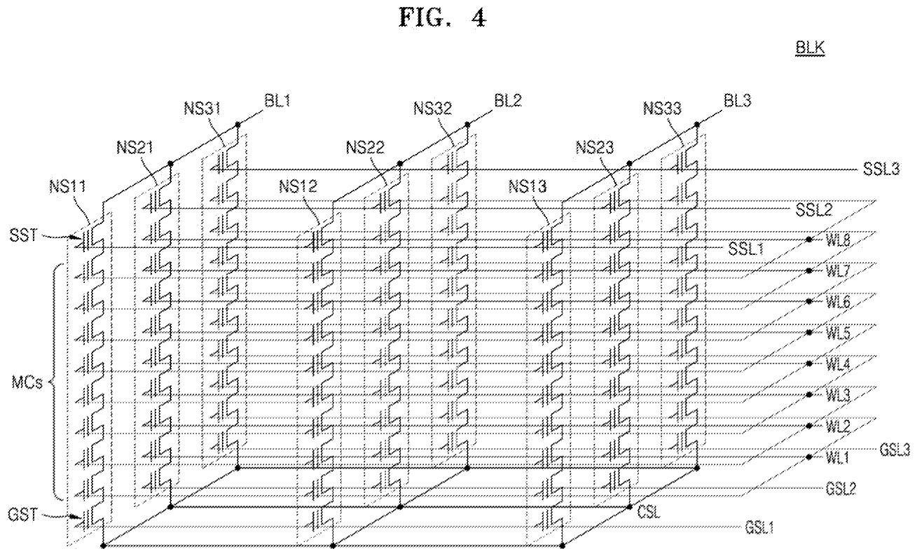

In an embodiment, the memory cell array 100 may include a three-dimensional memory cell array, and the three-dimensional memory cell array may include a plurality of NAND strings, and each of the plurality of NAND strings may include memory cells respectively connected to word lines vertically stacked on a substrate. This will be described in detail with reference to FIGS. 3 and 4. In some embodiments, the memory cell array 100 may include a two-dimensional memory cell array, and the two-dimensional memory cell array may include a plurality of NAND strings arranged in row and column directions.

The control logic 230 may program data into the memory cell array 100, read data from the memory cell array 100, or generate various control signals for erasing data stored in the memory cell array 100, based on a command CMD), an address ADDR, and a control signal CTRL. In an implementation, the control logic 230 may output a row address X-ADDR and a column address Y-ADDR. Accordingly, the control logic 230 may generally control various operations within the memory device 10.

The row decoder 220 may output, to the block selection signal lines BS, a block selection signal for selecting one of a plurality of memory blocks, in response to the row address X-ADDR. Also, the row decoder 220 may output a word line driving signal for selecting one of the word lines WIL of the selected memory block to the word line driving signal lines SI, output a string selection line driving signal for selecting one of the string selection lines SSL to the string selection line driving signal lines SS, and output a ground selection line driving signal for selecting one of the ground selection lines GSL to the ground selection line driving signal lines GS, in response to the row address X-ADDR. The page buffer 240 may select some of the bit lines BL in response to the column address Y-ADDR. In particular, the page buffer 240 may operate as a write driver or a sense amplifier according to an operation mode.

As a semiconductor process is developed, the number of pass transistors for driving word lines WL increases as the number of stages of memory cells in the memory cell array 100 increases, that is, as the number of word lines WL stacked in a vertical direction increases, an area occupied by the pass transistor circuit 210 may be increased. An area of the memory cell array 100 is reduced as the number of word lines WL stacked in the vertical direction may increase. In a case where a memory device is implemented as a cell over periphery (COP) structure, when the area of the memory cell array 100 is reduced, a peripheral circuit area below the memory cell array 100 may also be reduced, and thus it may be difficult to place the entire peripheral circuit 200 below the memory cell array 100.

FIG. 2 is a diagram showing a structure of a memory device according to an example embodiment. Referring to FIGS. 1 and 2 together, the memory device 10 may include the first semiconductor layer L1 and the second semiconductor layer L2, the first semiconductor layer L1 may be stacked in a vertical direction (Z axis direction) with respect to the second semiconductor layer L2. In particular, the second semiconductor layer L2 may be below the first semiconductor layer L1 in the vertical direction (Z axis direction).

In an embodiment, the memory cell array 100, the pass transistor circuit 210, and the row decoder 220 may be formed in the first semiconductor layer L1, and the control logic 230 and the page buffer 240 may be formed in the second semiconductor layer L2. Accordingly, the memory device 10 may have a structure in which the memory cell array 100 may be above a portion of a peripheral circuit, that is, a COP structure. The COP structure may effectively reduce an area of the memory device 10 in a horizontal direction and improve the degree of integration of the memory device 10.

In an embodiment, the first semiconductor layer L1 and the second semiconductor layer L2 may each include a substrate. The memory cell array 100, the pass transistor circuit 210, and the row decoder 220 may be formed on the substrate of the first semiconductor layer L1. Circuits including the control logic 230 and the page buffer 240 may be formed in the second semiconductor layer L2 by forming semiconductor elements, such as transistors, and patterns for wiring the elements on the substrate of the second semiconductor layer L2. After the circuits are formed in the second semiconductor layer L2, the first semiconductor layer L1 may be formed, and patterns for electrically connecting the bit lines BL of the memory cell array 100 and the circuits formed in the second semiconductor layer L2 to each other or patterns for electrically connecting the row decoder 220 and the circuits formed in the second semiconductor layer L2 to each other may be formed. The first semiconductor layer L1 and the second semiconductor layer L2 may be coupled to each other through wafer bonding.

In some other embodiments, the memory cell array 100 and the row decoder 220 may be formed on the substrate of the first semiconductor layer L1. Circuits including the control logic 230, the pass transistor circuit 210, and the page buffer 240 may be formed in the second semiconductor layer L2 by forming semiconductor elements, such as transistors, and patterns for wiring the elements on the substrate of the second semiconductor layer L2.

FIG. 3 is a diagram showing a memory cell array according to an example embodiment. Referring to FIG. 3, the memory cell array 100 may include a plurality of memory blocks BLK1 to BLKi, wherein “i” is a positive integer. Each of the plurality of memory blocks BLK1 to BLKi may have a three-dimensional structure (or a vertical structure). In particular, each of the plurality of memory blocks BLK1 to BLKi may include a plurality of NAND strings each extending in a vertical direction Z. In this case, the plurality of NAND strings may be spaced apart from each other by a particular distance in first and second horizontal directions X and Y. The plurality of memory blocks BLK1 to BLKi may be selected by the row decoder 220 (shown in FIG. 1). In an implementation, the row decoder 220 may select a memory block corresponding to a block address from among the plurality of memory blocks BLK1 to BLKi.

FIG. 4 is a diagram showing an equivalent circuit of a memory block BLK according to an example embodiment. In an implementation, the memory block BLK may correspond to one of the plurality of memory blocks BLK1 to BLKi in FIG. 3.

Referring to FIG. 4, the memory block BLK may include a plurality of NAND strings NS11 to NS33, a plurality of word lines WL1 to WL8, a plurality of bit lines including first to third bit lines BL1 to BL3, a plurality of ground selection lines GSL1 to GSL3, a plurality of string selection lines SSL1 to SSL3, and a common source line CSL. Here, the number of NAND strings, the number of word lines, the number of bit lines, the number of ground selection lines, and the number of string selection lines may be variously changed according to embodiments.

The NAND strings NS11, NS21, and NS31 may be provided between the first line BL1 and the common source line CSL, the NAND strings NS12, NS22, and NS32 may be provided between the second bit line BL2 and the common source line CSL, and the NAND strings NS13, NS23, and NS33 may be provided between the third bit line BL3 and the common source line CSL. Each NAND string (e.g., NS11) may include a string selection transistor SST, a plurality of memory cells MCS, and a ground selection transistor GST, which may be connected in series.

The string selection transistors SST may be respectively connected to corresponding string selection lines SSL1, SSL2, and SSL3. The plurality of memory cells MC1 to MC8 may be respectively connected to corresponding word lines WL1 to WL8. The ground selection transistors GST may be respectively connected to corresponding ground selection lines GSL1, GSL2, and GSL3. The string selection transistors SST may be respectively connected to corresponding bit lines BL1, BL2, and BL3, and the ground selection transistor GST may be connected to the common source line CSL.

In an embodiment, word lines (e.g., WL1) of the same height may be commonly connected to each other, the string selection lines SSL1 to SSL3 may be separated from each other, and the ground selection lines GSL1 to GSL3 may be also separated from each other. FIG. 4 illustrates that three string selection lines SSL1 to SSL3 share word lines having the same height. In an implementation, two string selection lines may share word lines having the same height. As another example, four string selection lines may share word lines having the same height.

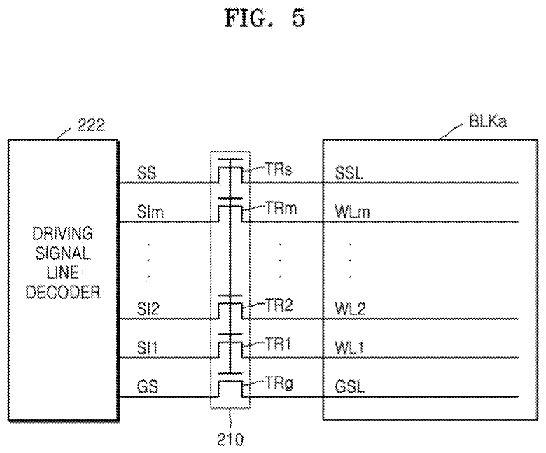

FIG. 5 is a diagram showing a driving signal line decoder, a pass transistor circuit, and a memory block, according to an example embodiment. Referring to FIG. 5, a memory block BLKa may correspond to one of the plurality of memory blocks BLK1 to BLKi (wherein a may be a positive integer). The row decoder 220 may correspond to the row decoder 220 of FIG. 1, and the pass transistor circuit 210 may correspond to an implementation example of the pass transistor circuit 210 of FIG. 1. Accordingly, descriptions made above with reference to FIGS. 1 to 4 may be applied to the present embodiment.

The row decoder 220 may include a block decoder 221 and a driving signal line decoder 222. The pass transistor circuit 210 may include a plurality of pass transistors TRs, TR1 to TRm, and TRg. The pass transistor circuit 210 may be provided for each of the plurality of memory blocks BLK1 to BLKi (shown in FIG. 3), and the block decoder 221 and the driving signal line decoder 222 may be commonly provided in the plurality of memory blocks BLK1 to BLKi (shown in FIG. 3).

The block decoder 221 may be connected to the pass transistor circuit 210 through the block selection signal line BS (shown in FIG. 1). In particular, the block selection signal line BS may be connected to the plurality of pass transistors TRs, TR1 to TRm, and TRg. In an implementation, when a block selection signal provided through the block selection signal line BS is activated, the plurality of pass transistors TRs, TR1 to TRm, and TRg may be turned on, and accordingly, the memory block BLKa may be selected.

The driving signal line decoder 222 may be connected to the pass transistor circuit 210 through a string selection line driving signal line SS, word line driving signal lines SI1 to SIm, and a ground selection line driving signal line GS. In particular, the string selection line driving signal line SS, the word line driving signal lines SI1 to SIm, and the ground selection line driving signal line GS may be respectively connected to sources of the plurality of pass transistors TRs, TR1 to TRm, and TRg.

The pass transistor circuit 210 may be connected to the memory block BLKa through a ground selection line GSL, a plurality of word lines WL1 to WLm, and a string selection line SSL. The pass transistors TR1 to TRm may respectively be connected to the word line driving signal lines SI1 to SIm corresponding to the plurality of word lines WL1 to WLm. The pass transistor TRs may be connected to the string selection line driving signal line SS corresponding to the string selection line SSL. The pass transistor TRg may be connected to the ground selection line driving signal line GS corresponding to the ground selection line GSL. In an implementation, when a block selection signal is activated, the pass transistors TRs, TR1 to TRm, and TRg may respectively provide driving signals provided through the string selection line driving signal line SS, the word line driving signal lines SI1 to SIm, and the ground selection line driving signal line GS to the string selection line SSL, the plurality of word lines WL1 to WLm, and the ground selection line GSL.

In an embodiment, the pass transistors TRs, and TR1 to TRm may be implemented as vertical pass transistors. Here, a “vertical pass transistor” is referred to as a transistor including a vertical channel.

FIG. 6 is a diagram showing a pass transistor array according to an example embodiment. Referring to FIG. 6, according to an embodiment, the pass transistor circuit 210 may include a plurality of pass transistor arrays including first and second pass transistor arrays 210a and 210b. In an embodiment, the first and second pass transistor arrays 210a and 210b may be parallel to each other. Despite of the increase in the number of pass transistors TR1 and TR2 according to the increase in the number of stacked word lines WL, an increase in the chip size of the memory device 10 may be prevented by arranging the first and second pass transistor arrays 210a and 210b.

The plurality of pass transistor arrays 210a and 210b may each include a plurality of vertical pass transistors (e.g., first to fourth vertical pass transistors TR1, TR2, TR3, and TR4), and an active region act. Here, for convenience of description, descriptions are made based on the first pass transistor array 210a.

The first pass transistor array 210a may include a first vertical pass transistor TR1, a second vertical pass transistor TR2, the active region act, and a main contact 210M. The first and second vertical pass transistors TR1 and TR2 may respectively be connected a plurality of driving signal lines and a plurality of word lines.

In an embodiment, the first vertical pass transistor TR1 and the second vertical pass transistor TR2 may share a, e.g., same, drain of the active region act. The first vertical pass transistor TR1 and the second vertical pass transistor TR2 may share the main contact 210M. The main contact 210M may be connected to the active region act to apply a signal to the active region act.

The first and second pass transistor arrays 210a and 210b may be parallel to each other on the same plane, e.g., bottoms of the first and second pass transistor arrays 210a and 210b may be coplanar. In this case, the first and second pass transistor arrays 210a and 210b may be parallel to a substrate.

The active region act of each of the first pass transistor array 210a and the second pass transistor array 210b may be parallel to a second direction D2 perpendicular to a first direction D1. In this case, the first direction D1 may be a direction perpendicular to an upper surface of a substrate, and the second direction D2 may be a direction of a line AA′ of FIG. 6.

A gate 2101 of the first vertical pass transistor TR1 may be arranged in a third direction D3 having a certain angle with the second direction D2. In an implementation, the certain angle may be a first angle, which may be an acute angle with respect to the second direction D2, or a 45 degrees angle with respect to the second direction D2. In an implementation, referring to FIG. 6, the third direction D3 may be inclined at an acute angle with respect to the second direction D2. In an implementation, the third direction D3 may be inclined at 45 degrees with respect to the second direction D2. Gates on the first vertical pass transistor TR1 and the second vertical pass transistor TR2 may be parallel to each other. Also, gates on the first pass transistor array 210a and the second pass transistor array 210b may be parallel to each other. Gates on the first pass transistor array 210a and the second pass transistor array 210b may both have a long axis extending at the same angle from the second direction D2 (e.g., extending in the third direction D3). The first and second pass transistor arrays 210a and 210b may occupy a minimum cross-sectional area.

The first vertical pass transistor TR1 and the second vertical pass transistor TR2 may be parallel to each other with a certain distance therebetween. The certain distance may be a first distance, which may be equally spaced intervals with respect to the main contact 210M. The first vertical pass transistor TR1 and the second vertical pass transistor TR2 may be spaced apart from each other at equal intervals with respect to the main contact 210M.

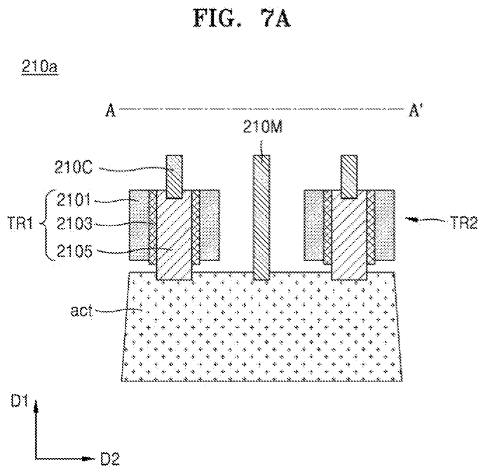

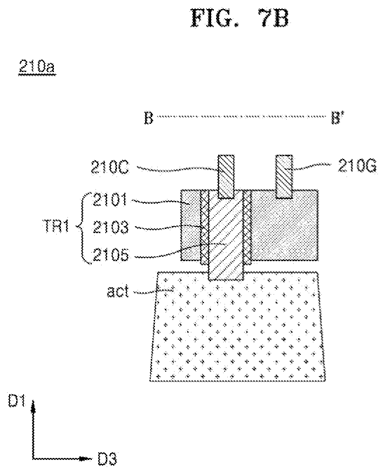

FIG. 7A is a cross-sectional view showing the first pass transistor array 210a taken along line AA′ of FIG. 6. FIG. 7B is a cross-sectional view showing the first pass transistor array 210a taken along line BB′ of FIG. 6.

Referring to FIGS. 7A and 7B, the first and second vertical pass transistors TR1 and TR2 according to an embodiment may each include the gate 2101, a gate insulating film 2103, and a vertical channel 2105.

The gate 2101 may extend in the first direction D1. The vertical channel 2105 may extend in the first direction D1 and pass through the gate 2101. The gate insulating film 2103 may be between the vertical channel 2105 and the gate 2101.

The first vertical pass transistor TR1 and the second vertical pass transistor TR2 may share the main contact 210M. The main contact 210M may be connected to the active region act to apply a signal to the active region act. The main contact 210M may be connected to the row decoder 220. The first vertical pass transistor TR1 and the second vertical pass transistor TR2 may each be connected to a contact 210C. The contact 210C may be connected to each word line of the memory cell array 100.

Each of the first vertical pass transistor TR1 and the second vertical pass transistor TR2 may receive a signal from the row decoder 220 through the main contact 210M. In an implementation, a program voltage V_{pgm} and a pass voltage Vₚₐₛₛ may be applied through the main contact 210M. The first vertical pass transistor TR1 and the second vertical pass transistor TR2 may deliver signals received from the row decoder 220 to respective word lines through the contact 210C.

Referring to FIG. 711, the first vertical pass transistor TR may further include a gate contact 210G. When a block selection signal provided from the row decoder 220 through the gate contact 210G and the block selection signal line BS is activated, the first vertical pass transistor TR1 may be turned on.

According to an embodiment, the first vertical pass transistor TR1 and the second vertical pass transistor TR2 may share the drain of the active region act. Also, the first vertical pass transistor TR1 and the second vertical pass transistor TR2 may share the main contact 210M. As the first and second vertical pass transistors TR1 and TR2 share the drain of the active region act and the main contact 210M, an area of the first pass transistor array 210a may be reduced.

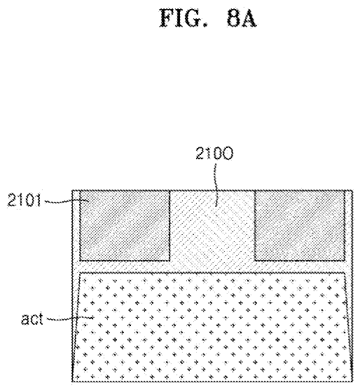

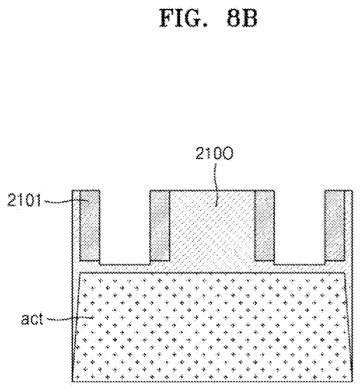

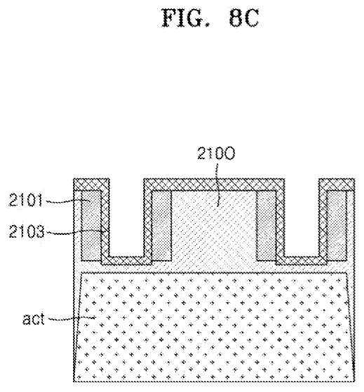

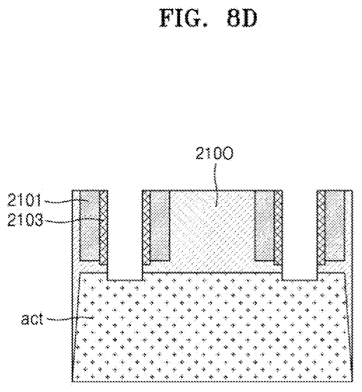

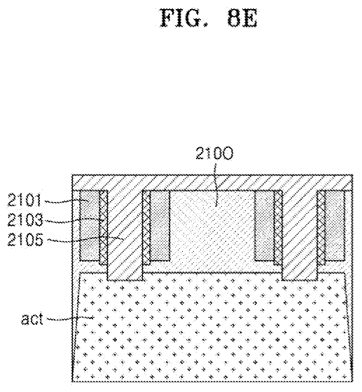

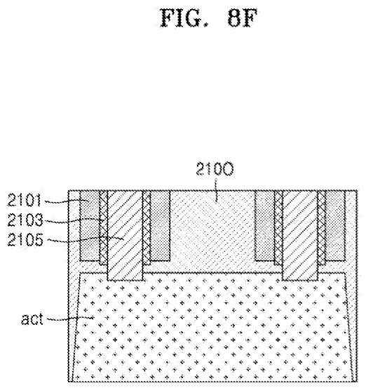

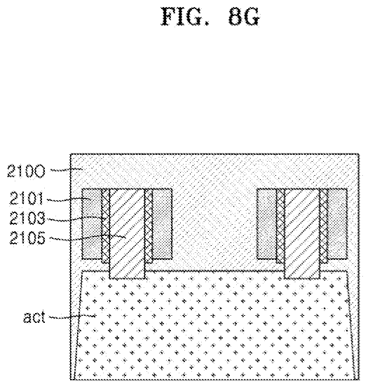

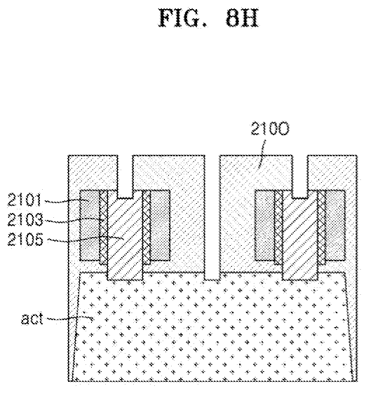

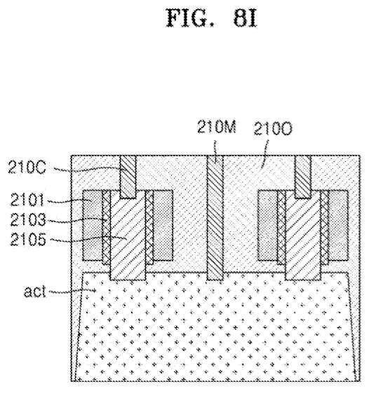

FIGS. 8A to 8I show steps in a method of forming a pass transistor array according to an example embodiment. Referring to FIG. 8A, the gate 2101 and an oxide film 2100 may be on the active region act. In this case, the gate 2101 of the first vertical pass transistor TR1 and a gate of the second vertical pass transistor TR2 may be spaced apart from each other. Also, a drain may be formed in the active region act so that the first vertical pass transistor TR1 and the second vertical pass transistor TR2 share the drain. Each gate may include polysilicon.

Referring to FIG. 8B, to form the vertical channel 2105, the gate 2101 may be etched to form an opening so that the gate 2101 is passed through. Referring to FIG. 8C, the gate insulating film 2103 may be grown in a region where the gate 2101 is passed through. The gate insulating film 2103 may be grown on a surface where the gate 2101 is passed through and an upper portion of the gate 2101 in the first direction D1.

Referring to FIG. 8D, the gate insulating film 2103 on the gate 2101 in the first direction D1 may be etched. Also, a portion of the gate insulating film 2103, which may be in contact with the oxide film 2100, may also be etched so that the vertical channel 2105 may pass through the gate 2101. Accordingly, the gate insulating film 2103 may also be passed through in the first direction D1.

Referring to FIG. 8E, the vertical channel 2105 of the first vertical pass transistor TR1 and the second vertical pass transistor TR2 may be formed. The vertical channel 2105 may pass through the gate 2101 in the first direction D1. In embodiments, the vertical channel 2105 may be formed as a region where the gate 2101 and the gate insulating film 2103 may be passed through. The vertical channel 2105 may include a silicon material, such as polysilicon. In this case, a source of the active region act may be on an upper end of the vertical channel 2105.

Referring to FIG. 8F, a silicon material on the gate 2101 in the first direction D1 may be removed. In an implementation, the silicon material may be removed by a chemical mechanical polishing (CMP) method. Referring to FIG. 8G, after the silicon material is removed, the oxide film 2100 may be deposited on the gate 2101 in the first direction D1.

Referring to FIG. 8H, after the oxide film 2100 is deposited, the oxide film 2100 may be etched to form the contacts 210C. Referring to FIG. 8i, a metal may be filled in a portion where the oxide film 2100 is etched to form contacts. In this case, the metal may be, e.g., tungsten (W). Referring to FIG. 8i, although the main contact 210M formed in the center and the contacts 210C connected to respective vertical pass transistors are shown, the gate contact 210G connected to the gate 2101 may also be similarly formed.

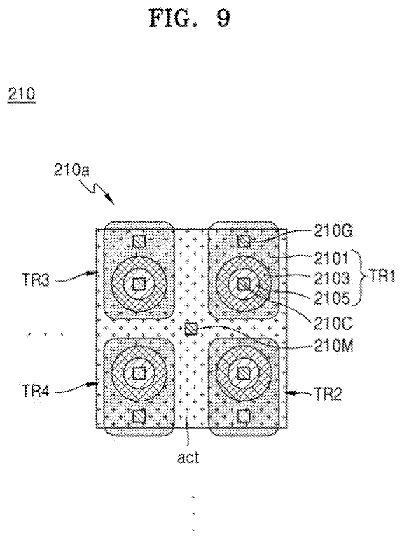

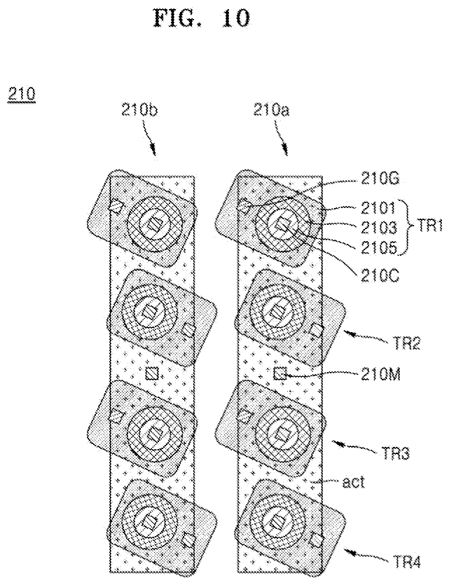

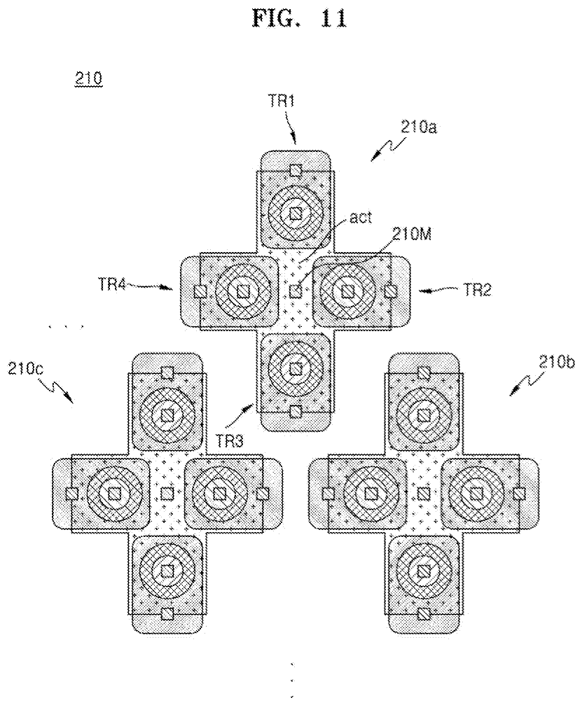

FIG. 9 is a diagram showing pass transistor arrays according to an example embodiment. FIG. 10 is a diagram showing pass transistor arrays according to an example embodiment. FIG. 11 is a diagram showing pass transistor arrays according to an example embodiment.

Referring to FIGS. 9 to 11, the first pass transistor array 210a according to an embodiment may include the first vertical pass transistor TR1 to the fourth vertical pass transistor TR4. The first vertical pass transistor TR1 to the fourth vertical pass transistor TR4 may share a drain of the active region act. Also, the first vertical pass transistor TR1 to the fourth vertical pass transistor TR4 may share the main contact 210M. The first vertical pass transistor TR1 to the fourth vertical pass transistor TR4 may be on the active region act parallel to each other with a certain distance therebetween.

The first to fourth vertical pass transistor TR1, TR2, TR3, and TR4 share the drain of the active region act and the main contact 210M, so that the area of the first pass transistor array 210a may be reduced. As a result, a total area of the pass transistor circuit 210 may be reduced.

As shown in FIG. 9, according to an embodiment, the first vertical pass transistor TR1 to the fourth vertical pass transistor TR4 may be on the active region act in a 2*2 form. The active region act of the first pass transistor array 210a may have a quadrangular shape, and the first vertical pass transistor TR1 to the fourth vertical pass transistor TR4 may respectively be positioned adjacent to corner portions of the active region act. The first vertical pass transistor TR1 to the fourth vertical pass transistor TR4 may be spaced apart from each other at equal intervals with respect to the main contact 210M. The pass transistor circuit 210 may be configured by gathering a plurality of first pass transistor arrays 210a each including the first to fourth vertical pass transistors TR1 to TR4 arranged in the 2*2 form.

The first vertical pass transistor TR1 to the fourth vertical pass transistor TR4 may be parallel to each other in the second direction D2 of FIG. 6. Arrangement directions of the first vertical pass transistor TR1 to the fourth vertical pass transistor TR4 may be differently designed as needed.

As shown in FIG. 10, according to an embodiment, the first vertical pass transistor TR1 to the fourth vertical pass transistor TR4 may be arranged on the active region act in a 1*4 form. The active region act of the first pass transistor array 210a may have a long quadrangular shape in the second direction D2 of FIG. 6. The first vertical pass transistor TR1 to the fourth vertical pass transistor TR4 may be parallel to each other in a line. The pass transistor circuit 210 may be configured by gathering the first and second pass transistor arrays 210a and 210b each including the first to fourth vertical pass transistors TR1 to TR4 arranged in the 1*4 form.

The first vertical pass transistor TR1 to the fourth vertical pass transistor TR4 may be parallel to each other and may have a certain angle with respect to the second direction D2 of FIG. 6. Arrangement directions of the first vertical pass transistor TR1 to the fourth vertical pass transistor TR4 may be differently designed as needed.

As shown in FIG. 11, according to an embodiment, the first vertical pass transistor TR1 to the fourth vertical pass transistor TR4 may be arranged on the active region act in a ‘+’ form. The active region act of the first pass transistor array 210a may have a ‘+’ shape. The first vertical pass transistor TR1 to the fourth vertical pass transistor TR4 may respectively be arranged at end portions of the active region act.

The first vertical pass transistor TR1 to the fourth vertical pass transistor TR4 may be spaced apart from each other at equal intervals with respect to the main contact 210M. The first vertical pass transistor TR1 to the fourth vertical pass transistor TR4 may be a radial shape with respect to the main contact 210M.

The first vertical pass transistor TR1 and the third vertical pass transistor TR3 may be parallel to the second direction D2 in a line. The second vertical pass transistor TR2 and the fourth vertical pass transistor TR4 may be parallel to a direction perpendicular to the second direction D2 in a line. The second vertical pass transistor TR2 may be perpendicular to the first vertical pass transistor TR1, the third vertical pass transistor TR3 may be perpendicular to the second vertical pass transistor TR2, and the fourth vertical pass transistor TR4 may be perpendicular to the third vertical pass transistor TR3. Arrangement directions of the first vertical pass transistor TR1 to the fourth vertical pass transistor TR4 may be differently designed as needed.

The pass transistor circuit 210 may be configured by gathering a plurality of pass transistor arrays including first to third pass transistor arrays 210a, 210b, and 210c, each including the first to fourth vertical pass transistors TR1 to TR4 arranged in the ‘+’ form.

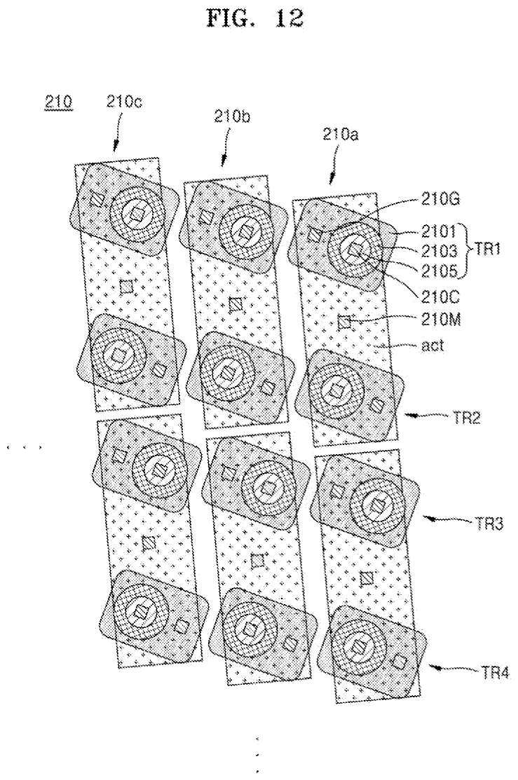

FIG. 12 is a diagram showing pass transistor arrays according to an example embodiment. Referring to FIG. 12, the first pass transistor array 210a according to an embodiment may include the first vertical pass transistor TR1 and the second vertical pass transistor TR2. The first vertical pass transistor TR1 and the second vertical pass transistor TR2 may share a drain of the active region act. Also, the first vertical pass transistor TR1 and the second vertical pass transistor TR2 may share the main contact 210M.

The active region act of each of the first to third pass transistor arrays 210a, 210b, and 210c may have a certain angle with the second direction D2 of FIG. 6. In an implementation, the active region act may be inclined. Active regions act of the first to third pass transistor arrays 210a, 210b, and 210c may be parallel to each other.

The active region act of each of the first to third pass transistor arrays 210a, 210b, and 210c may be inclined, so that a distance between adjacent active regions act may be reduced. As the distance between adjacent active regions act is reduced, a total area of the pass transistor circuit 210 may be reduced. Also, a breakdown problem of vertical pass transistors may be solved.

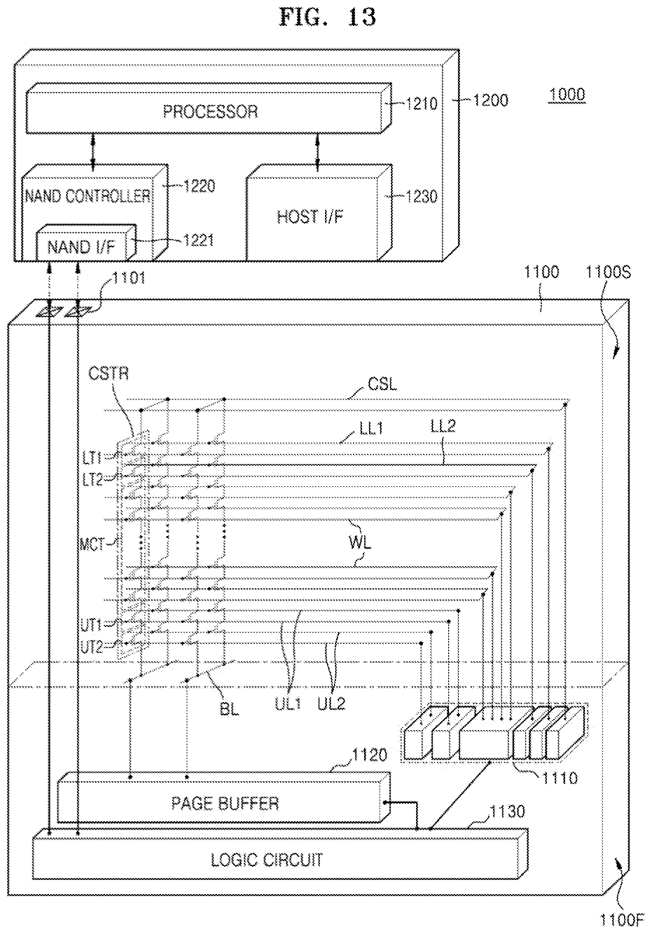

FIG. 13 is a diagram showing a data storage system 1000 including a memory device according to an example embodiment. Referring to FIG. 13, the data storage system 1000 may include one or more memory devices 1100, and a memory controller 1200 electrically connected to the one or more memory devices 1100. The data storage system 1000 may be, e.g., a solid state drive device (SSD) including at least one memory device 1100, a universal serial bus (USB), a computing system, or a medical device.

The memory device 1100 may be a non-volatile memory device, and e.g., the memory device 1100 may be a NAND flash memory device including the memory device 10 described above with reference to FIGS. 1 to 12. The memory device 1100 may include a first structure 1100F and a second structure 1100S on the first structure 1100F. The first structure 1100F may include a row decoder 1110, a page buffer 1120, and a logic circuit 1130.

The second structure 1100S may include a bit line BL, a common source line CSL, a plurality of word lines WL, first and second string selection lines UL1 and UL2, first and second ground selection lines LL1 and LL2, and a plurality of memory cell strings CSTR between the bit line BL and the common source line CSL.

In the second structure 1100S, the plurality of memory cell strings CSTR may each include ground selection transistors LT1 and LT2, which may be adjacent to the common source line CSL, string selection transistors UT1 and UT2, which may be adjacent to the bit line BL, and a plurality of memory cell transistors MCT between the ground selection transistors LT1 and LT2 and the string selection transistors UT1 and UT2. The number of ground selection transistors LT1 and LT2 and the number of string selection transistors UT1 and UT2 may be variously changed according to embodiments.

In embodiments, the first and second ground selection lines LL1 and LL2 may respectively be connected to gate electrodes of the ground selection transistors LT1 and LT2. A word line WL may be connected to a gate electrode of a memory cell transistor MCT. The first and second string selection lines UL1 and UL2 may respectively be connected to gate electrodes of the string selection transistors UT1 and UT2.

The common source line CSL, the first and second ground selection lines LL1 and LL2, and the first and second string selection lines UL1 and UL2 may be connected to the row decoder 1110. A plurality of bit lines BL may be electrically connected to the page buffer 1120.

The memory device 1100 may communicate with the memory controller 1200 through an input/output pad 1101 electrically connected to the logic circuit 1130. The input/output pad 1101 may be electrically connected to the logic circuit 1130.

The memory controller 1200 may include a processor 1210, a NAND controller 1220, and a host interface 1230. In some embodiments, the data storage system 1000 may include a plurality of memory devices 1100, and in this case, the memory controller 1200 may control the plurality of memory devices 1100.

The processor 1210 may control an overall operation of the data storage system 1000 including the memory controller 1200. The processor 1210 may operate according to certain firmware, and may access the memory device 1100 by controlling the NAND controller 1220. The NAND controller 1220 may include a NAND interface 1221 processing communication with the memory device 1100. A control command for controlling the memory device 1100, data to be written to the plurality of memory cell transistors MCT of the memory device 1100, and data to be read from the plurality of memory cell transistors MCT of the memory device 1100, may be transmitted through the NAND interface 1221. The host interface 1230 may provide a communication function between the data storage system 1000 and an external host. When a control command is received from an external host through the host interface 1230, the processor 1210 may control the memory device 1100 in response to the control command.

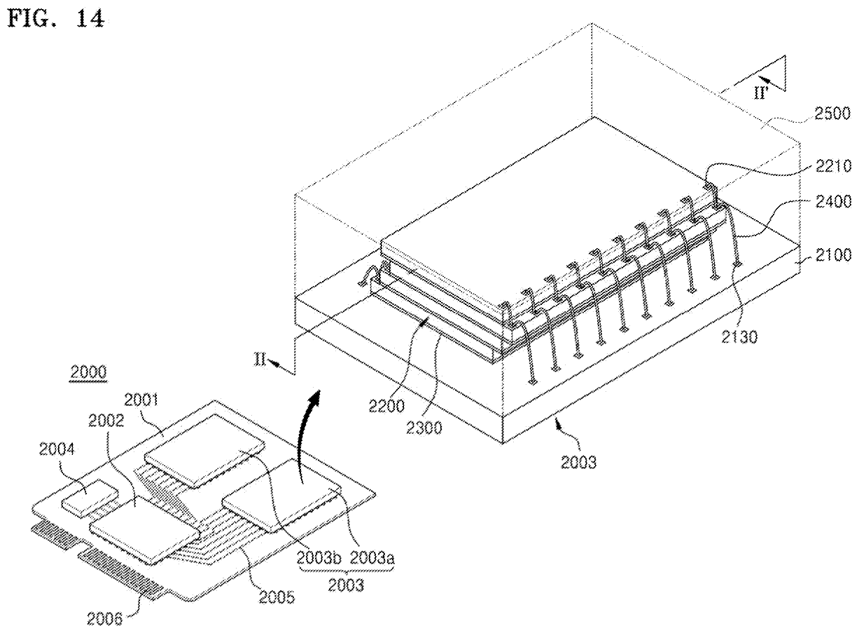

FIG. 14 is a perspective view showing a data storage system 2000 including a memory device according to an example embodiment. Referring to FIG. 14, the data storage system 2000 according to an embodiment may include a main substrate 2001, a memory controller 2002 mounted on the main substrate 2001, one or more semiconductor packages 2003, and dynamic random access memory (DRAM) 2004. Each of the plurality of semiconductor packages 2003 and the DRAM 2004 may be connected to the memory controller 2002 by a plurality of wire patterns 2005 on the main substrate 2001.

The main substrate 2001 may include a connector 2006 including a plurality of pins coupled to an external host. The number and arrangement of the plurality of pins in the connector 2006 may vary depending on a communication interface between the data storage system 2000 and the external host. In embodiments, the data storage system 2000 may communicate with an external host depending on any one of interfaces, such as USB, peripheral component interconnect express (PCI-Express), serial advanced technology attachment (SATA), or M-Phy for universal flash storage (UFS). In embodiments, the data storage system 2000 may be operated by power supplied from an external host through the connector 2006. The data storage system 2000 may further include a power management integrated circuit distributing power supplied from the external host to the memory controller 2002 and the semiconductor package 2003.

The memory controller 2002 may write data to the semiconductor package 2003 or read data from the semiconductor package 2003, and may improve an operating speed of the data storage system 2000.

The DRAM 2004 may be a buffer memory for relieving a speed difference between the semiconductor package 2003, which may be a data storage space, and an external host. The DRAM 2004 included in the data storage system 2000 may also operate as a kind of cache memory, and may provide a space for temporarily storing data in a control operation for the semiconductor package 2003. When the DRAM 2004 is included in the data storage system 2000, the memory controller 2002 may further include a DRAM controller for controlling the DRAM 2004, in addition to a NAND controller for controlling the semiconductor package 2003.

The semiconductor package 2003 may include first and second semiconductor packages 2003a and 2003b. The first and second semiconductor packages 2003a and 2003b may each be a semiconductor package including a plurality of semiconductor chips 2200. The first and second semiconductor packages 2003a and 2003b may each include a package substrate 2100, the plurality of semiconductor chips 2200 on the package substrate 2100, an adhesive layer 2300 on a lower surface of each of the plurality of semiconductor chips 2200, a connection structure 2400 electrically connecting the plurality of semiconductor chips 2200 and the package substrate 2100 to each other, and a molding layer 2500 covering the plurality of semiconductor chips 2200 and the connection structure 2400 on the package substrate 2100.

The package substrate 2100 may be a printed circuit board including a plurality of package upper pads 2130. Each of the plurality of semiconductor chips 2200 may include an input/output pad 2210. The input/output pad 2210 may correspond to the input/output pad 1101 of FIG. 13. Each of the plurality of semiconductor chips 2200 may include the memory device 10 described with reference to FIGS. 1 to 12.

In embodiments, the connection structure 2400 may be a bonding wire electrically connecting the input/output pad 2210 and a package upper pad 2130 to each other. Accordingly, in the first and second semiconductor packages 2003a and 2003b, the plurality of semiconductor chips 2200 may be electrically connected to each other in a bonding wire method, and may be electrically connected to the package upper pad 2130 of the package substrate 2100. In embodiments, in the first and second semiconductor packages 2003a and 2003b, the plurality of semiconductor chips 2200 may also be electrically connected to each other by a connection structure including a through silicon via (TSV) instead of the connection structure 2400 of a bonding wire method.

In embodiments, the memory controller 2002 and the plurality of semiconductor chips 2200 may also be included in one package. In an embodiment, the memory controller 2002 and the plurality of semiconductor chips 2200 may be mounted on a separate interposer substrate different from the main substrate 2001, and the memory controller 2002 and the plurality of semiconductor chips 2200 may also be connected to each other by a wire formed on the interposer substrate.

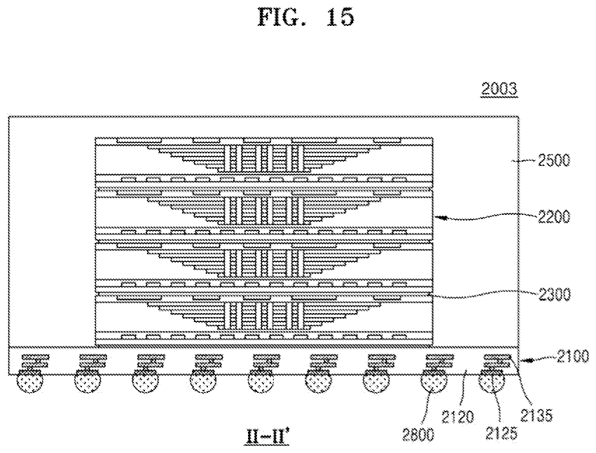

FIG. 15 is a cross-sectional view showing the semiconductor package taken along line II-II′ of FIG. 14. Referring to FIG. 15, in a semiconductor package 2003, the package substrate 2100 may be a printed circuit board. The package substrate 2100 may include a package substrate body portion 2120, the plurality of package upper pads 2130 (shown in FIG. 14) on an upper surface of the package substrate body portion 2120, a plurality of lower pads 2125 arranged on or exposed through a lower surface of the package substrate body portion 2120, and a plurality of internal wires 2135 inside the package substrate body portion 2120 and electrically connecting the plurality of package upper pads 2130 (shown in FIG. 14) and the plurality of lower pads 2125 to each other. As shown in FIG. 14, the plurality of package upper pads 2130 may respectively be electrically connected to a plurality of connection structures 2400. As shown in FIG. 15, the plurality of lower pads 2125 may respectively be connected to the plurality of wire patterns 2005 on the main substrate 2001 of the data storage system 2000 shown in FIG. 14 through a plurality of conductive bumps 2800. Each of the plurality of semiconductor chips 2200 may include the memory device 10 described with reference to FIGS. 1 to 12.

By way of summation and review, a non-volatile device having a cell-over-periphery (COP) structure is disclosed. As the size of a memory cell is reduced for high integration, operating circuits and/or line structures included in a memory device may become more complicated for operation and electrical connection of the memory device. Accordingly, a memory device having improved degree of integration of the memory device and excellent electrical characteristics is required. In particular, to improve the degree of integration of the memory device, the number of word lines stacked in a direction perpendicular to a substrate may increase. At this time, the number of pass transistors connected to the word lines may increase, and thus increasing a chip size.

In contrast, example embodiments provide a non-volatile memory device in which a chip size thereof may be reduced while the degree of integration thereof is improved. Example embodiments also provide a non-volatile memory device in which a pass transistor array may reduce a total area of a pass transistor circuit. Like reference numerals in the drawings denote like elements, and thus their description will be omitted.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made.

What is claimed is:

1. A non-volatile memory device comprising:
a memory cell array including a plurality of word lines stacked on a substrate in a first direction perpendicular to an upper surface of the substrate, and a common source line below the plurality of word lines;
a plurality of driving signal lines connected to a row decoder; and
a plurality of pass transistor arrays each including a plurality of vertical pass transistors respectively connected the plurality of driving signal lines and the plurality of word lines,
wherein each of the plurality of pass transistor arrays further include an active region including a drain to which at least two of the plurality of vertical pass transistors are simultaneously bonded, and a main contact applying a signal, to the active region.

2. The non-volatile memory device as claimed in claim 1, wherein each of the plurality of vertical pass transistors include:
a gate extending in the first direction;
a vertical channel penetrating the gate in the first direction; and
a gate insulating film between the vertical channel and the gate.

3. The non-volatile memory device as claimed in claim 1, wherein the pass transistor array further includes a contact respectively connecting the plurality of vertical pass transistors and the plurality of word lines to each other.

4. The non-volatile memory device as claimed in claim 2, wherein:
the active region is parallel to a second direction perpendicular to the first direction, and
the gate has a first angle with the second direction.

5. The non-volatile memory device as claimed in claim 1, wherein the plurality of pass transistor arrays are on a plane parallel to the substrate parallel to each other.

6. The non-volatile memory device as claimed in claim 1, wherein the pass transistor array further includes a first vertical pass transistor and a second vertical pass transistor sharing one drain, and the first vertical pass transistor and the second vertical pass transistor are arranged with a first distance therebetween.

7. The non-volatile memory device as claimed in claim 1, wherein the pass transistor array further includes first to fourth vertical pass transistors sharing one drain, and the first to fourth vertical pass transistors are arranged with a first distance between each other.

8. The non-volatile memory device as claimed in claim 7, wherein the first to fourth vertical pass transistors are arranged in a 1*4 form.

9. The non-volatile memory device as claimed in claim 7, wherein the first to fourth vertical pass transistors are arranged in a 2*2 form.

10. The non-volatile memory device as claimed in claim 7, wherein:
a horizontal cross section of the active region is in a ‘+’ shape, and
the first to fourth vertical pass transistors are respectively arranged at end portions of the active region.

11. The non-volatile memory device as claimed in claim 1, wherein the pass transistor array has a first angle with a second direction perpendicular to the first direction.

12. The non-volatile memory device as claimed in claim 11, wherein the plurality of pass transistor arrays are parallel to each other.

13. The non-volatile memory device as claimed in claim 1, wherein the plurality of vertical pass transistors are on the active region in a radial shape with respect to the main contact.

14. A non-volatile memory device comprising:
a memory cell array including a first word line, a second word line stacked on the first word line, a third word line stacked on the second word line, and a fourth word line stacked on the third word line; and
first to fourth vertical pass transistors respectively connected to the first word line to the fourth word line,
wherein two or more of the first to fourth vertical pass transistors share one drain of an active region.

15. The non-volatile memory device as claimed in claim 14, wherein:
the first vertical pass transistor and the second vertical pass transistor share a drain of a first active region, and
the third vertical pass transistor and the fourth vertical pass transistor share a drain of a second active region.

16. The non-volatile memory device as claimed in claim 15, wherein the first active region and the second active region are on a same plane parallel to each other.

17. The non-volatile memory device as claimed in claim 5, wherein the first active region and the second active region have a same size.

18. The non-volatile memory device as claimed in claim 14, wherein the first to fourth vertical pass transistors share a drain of one active region.

19. The non-volatile memory device as claimed in claim 18, wherein the first to fourth vertical pass transistors share one main contact.

20. An electronic system comprising:
a main substrate;
a non-volatile memory device on the main substrate; and
a controller electrically connected to the non-volatile memory device on the main substrate,
wherein the non-volatile memory device includes:
a first semiconductor layer including a memory cell array including a plurality of word lines stacked in a vertical direction and a common source line below the plurality of word lines, a row decoder, and a plurality of vertical pass transistors connected between the plurality of word lines and the row decoder; and
a second semiconductor layer including a page buffer connected to the memory cell array, and below the first semiconductor layer in the vertical direction, the plurality of vertical pass transistors sharing a drain of an active region and sharing a main contact, the main contact applying a signal to the active region.
